(19) United States
(12) Patent Application Publication
(10) Pub. No.: US 2025/0105120 A1
(43) Pub. Date: Mar. 27, 2025

(54) MANUFACTURING METHOD OF ELECTRONIC DEVICE HAVING THROUGH-HOLE SUBSTRATE AND ELECTRONIC DEVICE

(71) Applicant: Innolux Corporation, Miaoli County (TW)

(72) Inventors: Po-Yun Hsu, Miaoli County (TW); Ker-Yih Kao, Miaoli County (TW)

(73) Assignee: Innolux Corporation, Miaoli County (TW)

(21) Appl. No.: 18/813,059

(22) Filed: Aug. 23, 2024

Related U.S. Application Data
(60) Provisional application No. 63/540,116, filed on Sep. 25, 2023.

(30) Foreign Application Priority Data
Jun. 27, 2024 (CN) 202410847186.8

(51) Int. Cl. H01L 23/498; H01L 21/48

(52) U.S. Cl. CPC H01L 23/49827; H01L 21/486; H01L 23/49833

(57) ABSTRACT

A manufacturing method of an electronic device having a through-hole substrate includes: irradiating a partial region on two opposite surfaces of a substrate with a laser; and performing a through-hole formation step on the partial region of the substrate. The through-hole formation step includes: performing an etching step to form opposite etching profiles in the partial region on the two opposite surfaces of the substrate; performing a buffer layer coating step to form a buffer layer on the two opposite surfaces of the substrate and the opposite etching profiles; and repeating the etching step and the buffer layer coating step until the opposite etching profiles form a through hole. An electronic device is also provided.

### CROSS-REFERENCE TO RELATED APPLICATION

This application claims the priority benefit of U.S. provisional application Ser. No. 63/540,116, filed on Sep. 25, 2023, and China application serial no. 202410847186.8, filed on Jun. 27, 2024. The entirety of each of the above-mentioned patent applications is hereby incorporated by reference herein and made a part of this specification.

### BACKGROUND

### Technical Field

The disclosure relates to an electronic device and a manufacturing method thereof, and in particular to an electronic device having a through-hole substrate and a manufacturing method thereof.

### Description of Related Art

A manufacturing process of an electronic device is often accompanied by a thermal process. When an electronic element is bonded to a substrate, the mismatch in coefficient of thermal expansions may easily cause warping. Therefore, how to improve the structural strength of the substrate is a very important issue.

### SUMMARY

The disclosure provides an electronic device and a manufacturing method thereof, which help to improve the structural strength of a substrate.

In an embodiment of the disclosure, a manufacturing method of an electronic device having a through-hole substrate includes the following steps. A partial region on two opposite surfaces of a substrate is irradiated with a laser. A through-hole formation step is performed in the partial region of the substrate. The through-hole formation step includes performing an etching step to form opposite etching profiles in the partial region on the two opposite surfaces of the substrate; performing a buffer layer coating step to form a buffer layer on the two opposite surfaces of the substrate and the opposite etching profiles; and repeating the etching step and the buffer layer coating step until the opposite etching profiles form a through hole.

In another embodiment of the disclosure, an electronic device includes a through-hole substrate, a conductive member, an electronic element and a circuit board. The through-hole substrate has a first surface, a second surface opposite to the first surface, and a through hole. An inner wall of the through hole is connected to the first surface and the second surface. The conductive member is disposed in the through hole. The electronic element is disposed on the first surface and is electrically connected to the circuit board through the conductive member. A surface roughness of the first surface is greater than a surface roughness of the inner wall of the through hole.

In order for the features and advantages of the disclosure to be more comprehensible, the following specific embodiments are described in detail in conjunction with the drawings.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic view of a partial region on two opposite surfaces of a substrate irradiated with a laser.

FIG. 2 is a cross-sectional schematic view of performing an etching step.

FIG. 3 is a cross-sectional schematic view of performing a buffer layer coating step.

FIG. 4 is an enlarged schematic view of a region R1 of FIG. 3.

FIG. 5 is a cross-sectional schematic view of opposite etching profiles forming a through hole and an angle of the through hole being less than or equal to 20 degrees.

FIG. 6 and FIG. 7 are respectively enlarged schematic views of a region R2 and a region R3 of FIG. 5.

FIG. 8 is a schematic view of immersing a substrate irradiated with a laser in a mixed solution including an inhibitor and an etchant.

FIG. 9 is a schematic view of immersing a substrate formed with opposite cone holes in a mixed solution including an inhibitor and an etchant.

FIG. 10 to FIG. 14 are respectively cross-sectional schematic views of five electronic devices according to some embodiments of the disclosure.

### DESCRIPTION OF THE EMBODIMENTS

Reference will now be made in detail to the exemplary embodiments of the disclosure, and examples of the exemplary embodiments are illustrated in the drawings. Wherever possible, the same reference numerals are used in the drawings and the description to refer to the same or similar parts.

Throughout the specification and the appended claims of the disclosure, certain terms may be used to refer to specific elements. It should be understood by persons skilled in the art that electronic device manufacturers may refer to the same element by different names. The disclosure does not intend to distinguish between elements with the same function but different names. In the following specification and claims, words such as “containing” and “comprising” are open-ended words, so the words should be interpreted as “including but not limited to . . . ”.

Directional terms such as “upper”, “lower”, “front”, “rear”, “left”, and “right” mentioned in the disclosure are only directions with reference to the drawings. Therefore, the used directional terms are used to illustrate, but not to limit, the disclosure. In the drawings, each drawing illustrates the general characteristics of a method, a structure, and/or a material used in a specific embodiment. However, the drawings should not be construed to define or limit the scope or nature covered by the embodiments. For example, the relative sizes, thicknesses, and positions of various film layers, regions, and/or structures may be reduced or enlarged for clarity.

It should be understood that relative terms such as “lower” or “bottom” or “upper” or “top” may be used in various embodiments to describe the relative relationship of an element of the drawing to another element. It will be understood that if a device in the drawing is turned upside down, elements described as being on the “lower” side will then become elements on the “higher” side. The embodiments of the disclosure may be understood in conjunction with the drawings, and the drawings are also regarded as a part of the description of the disclosure.

When a structure (or layer, element, base material) is described in the disclosure as being located on/above another structure (or layer, element, base material), it may mean that the two structures are adjacent and directly connected or it may mean that the two structures are adjacent but indirectly connected. Indirect connection means that there is at least one intermediate structure (or intermediate layer, intermediate element, intermediate base material, intermediate spacing) between the two structures. A lower surface of one structure is adjacent or directly connected to an upper surface of the intermediate structure, and an upper surface of the other structure is adjacent or directly connected to a lower surface of the intermediate structure. The intermediate structure may be composed of a single-layer or multi-layer physical structure or non-physical structure, which is not limited. In the disclosure, when a certain structure is disposed “on” another structure, it may mean that the certain structure is “directly” on the other structure or it may mean that the certain structure is “indirectly” on the other structure, that is, at least one structure is also sandwiched between the certain structure and the other structure. In addition, the certain structure being disposed on the other structure is only for convenience of description and does not limit the process steps or sequence.

The terms “about”, “substantially”, or “roughly” are generally interpreted as within 10% of a given value or range or interpreted as within 5%, 3%, 2%, 1%, or 0.5% of the given value or range. In addition, the terms “a range is from a first value to a second value” and “the range is between the first value and the second value” mean that the range includes the first value, the second value, and other values therebetween.

Ordinal numbers such as “first” and “second” used in the description and the claims are used to modify elements and do not imply and represent that the elements have any previous ordinal numbers, nor do the ordinal numbers represent the sequence of a certain element and another element or the sequence of a manufacturing method. The use of the ordinal numbers is only used to clearly distinguish between an element with a certain name and another element with the same name. The claims and the specification may not use the same terms, whereby a first component in the specification may be a second component in the claims.

A connection described in the disclosure may include a physical connection or an electrical connection. The physical connection and the electrical connection may both include direct contact or indirect contact. In the case of direct contact or direct connection, end points of elements on two circuits are directly connected or connected to each other with a conductor line segment. In the case of indirect contact or indirect connection, there is a switch, a diode, a capacitor, an inductor, a resistor, other suitable elements, or a combination of the above elements between the end points of the elements on the two circuits, but not limited thereto.

In the disclosure, thickness, length, and width may be measured by adopting an optical microscope (OM), and thickness or width may be obtained by measuring a cross-sectional image in an electron microscope, but not limited thereto. For surface roughness, surface undulations may be observed using a scanning electron microscope (SEM), a transmission electron microscope (TEM), etc. at the same appropriate magnification, and a unit length (for example, 10 μm) may be taken to compare the undulations. The appropriate magnification means that a roughness or an average roughness of at least 10 undulating peaks is visible for at least one surface under a field of view of the magnification.

In addition, there may be a certain error between any two values or directions for comparison. In addition, the term “a given range is from a first value to a second value”, “the given range falls within a range of the first value to the second value”, or “the given range is between the first value and the second value” means that the given range includes the first value, the second value, and other values therebetween. If a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees.

Unless otherwise defined, all terms (including technical and scientific terms) used herein have the same meaning as commonly understood by persons skilled in the art to which the disclosure belongs. It can be understood that the terms such as the terms defined in commonly used dictionaries should be interpreted as having meanings consistent with the relevant art and the background or context of the disclosure, and should not be interpreted in an idealized or overly formal manner, unless otherwise defined in the embodiments of the disclosure.

In the disclosure, the electronic device may include a power device, a semiconductor packaging device, a display device, a backlight device, an antenna device, a packaging device, a sensing device, or a splicing device, but not limited thereto. The electronic device may be a bendable or flexible electronic device. The display device may be a non-self-luminous display device or a self-luminous display device. The display device may, for example, include liquid crystal, a light emitting diode, fluorescence, phosphor, quantum dot (QD), other suitable display media, or a combination of the above. The antenna device may, for example, include a reconfigurable intelligent surface (RIS), a frequency selective surface (FSS), a radio frequency filter (RF filter), a polarizer, a resonator, an antenna, etc. The antenna may be a liquid crystal antenna or a varactor diode antenna. The sensing device may be a sensing device for sensing capacitance, light, heat energy, or ultrasonic waves, but not limited thereto. In the disclosure, the electronic device may include an electronic element. The electronic element may include a passive element and an active element, such as a known good die (KGD), a capacitor, a resistor, an inductor, a diode, a transistor, a varactor diode, a variable capacitor, a filter, a sensor, microelectromechanical systems (MEMS), a liquid crystal chip, a structure of a semiconductor-related process, or a structure of a semiconductor-related process disposed on a substrate (for example, polyimide, glass, silicon base, or other suitable substrate materials), but not limited thereto. The diode may include a light emitting diode, a varactor diode, or a photodiode. The light emitting diode may, for example, include an organic light emitting diode (OLED), a mini LED, a micro LED, or a QD LED, but not limited thereto. The splicing device may, for example, be a display splicing device or an antenna splicing device, but not limited thereto. It should be noted that the electronic device may be any permutation and combination of the above, but not limited thereto. The packaging device may be a packaging device suitable for wafer-level package (WLP) technology or panel-level package (PLP) technology, such as chip first process or RDL first process. In addition, the appearance of the electronic device may be a rectangle, a circle, a polygon, a shape with curved edges, or other suitable shapes. The electronic device may have a peripheral system such as a driving system, a control system, and a light source system to support a display device, an antenna device, a wearable device (such as including augmented reality or virtual reality), a vehicle-mounted device (such as including a car windshield), or a splicing device. The following embodiments use the packaging device as an example to illustrate some implementation types of the electronic device, but not limited thereto. According to an embodiment of the disclosure, a manufacturing method of an electronic device having a through-hole substrate provided may be, for example, applied to a wafer-level package (WLP) or panel-level package (PLP) process and may adopt a chip first process or a chip last/RDL first process, which will be described in further detail below. According to an embodiment of the disclosure, a packaging structure of an electronic device may include a system on chip (SoC), a system in package (SiP), an antenna in package (AiP), or a combination of the above, but not limited thereto.

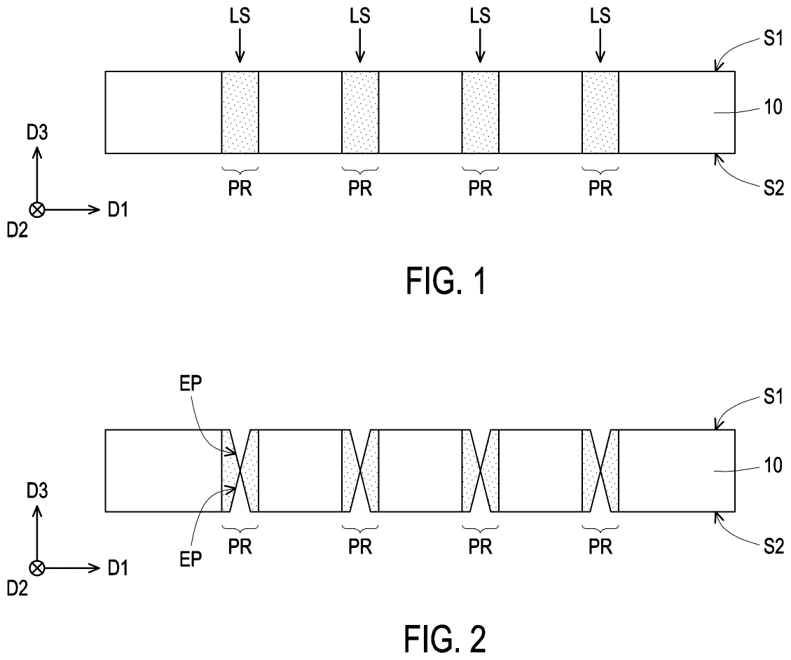

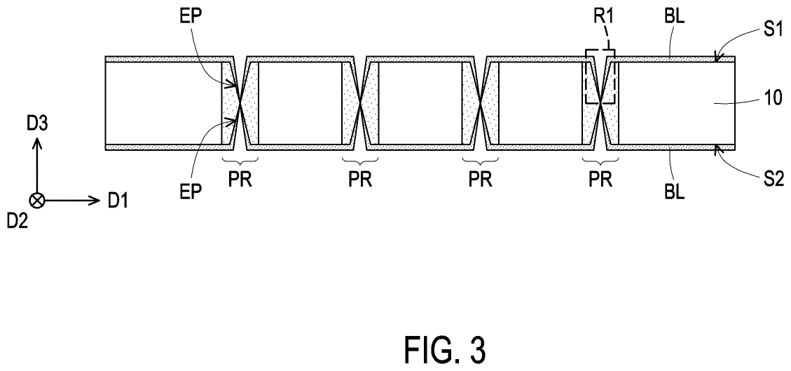

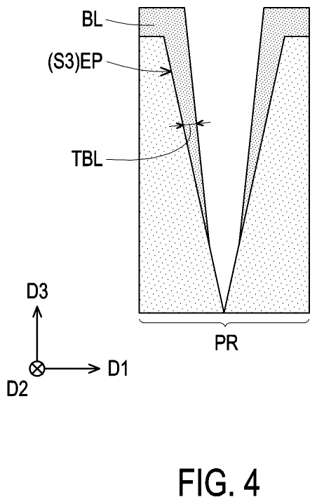

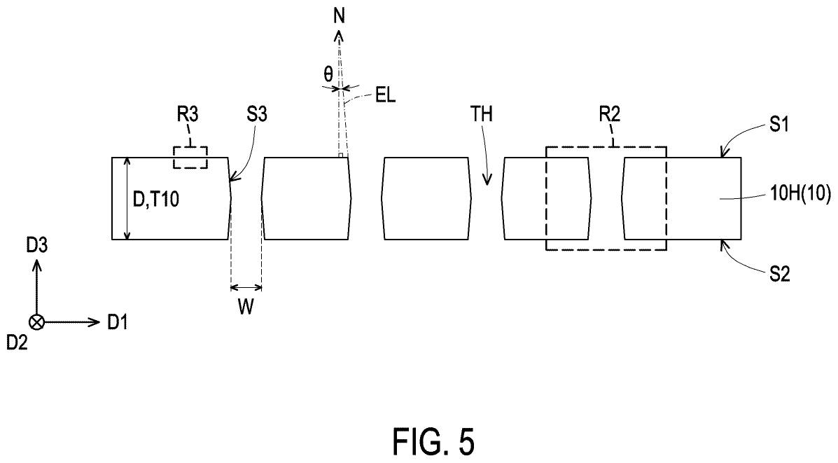

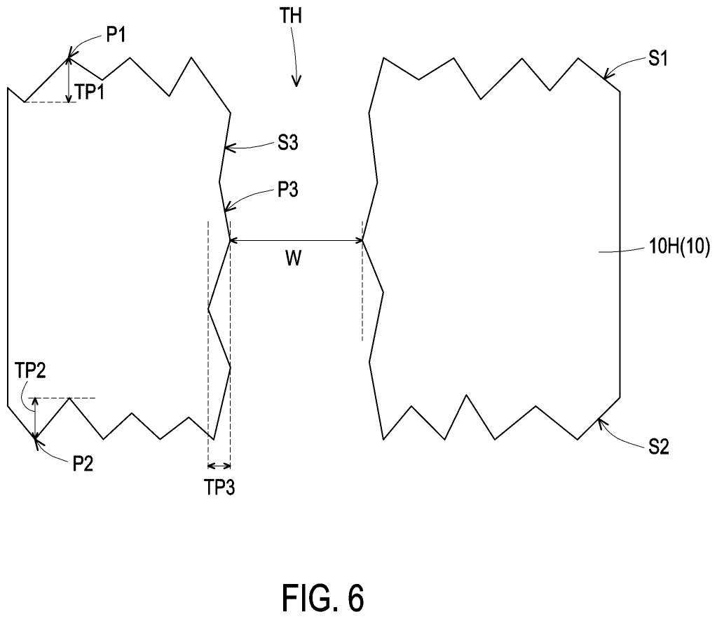

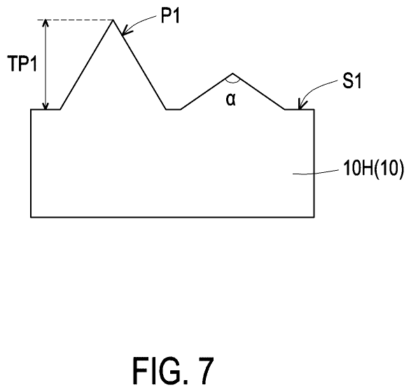

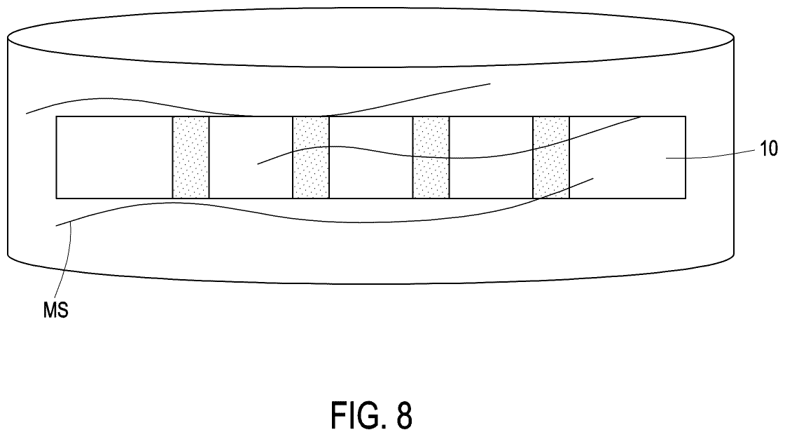

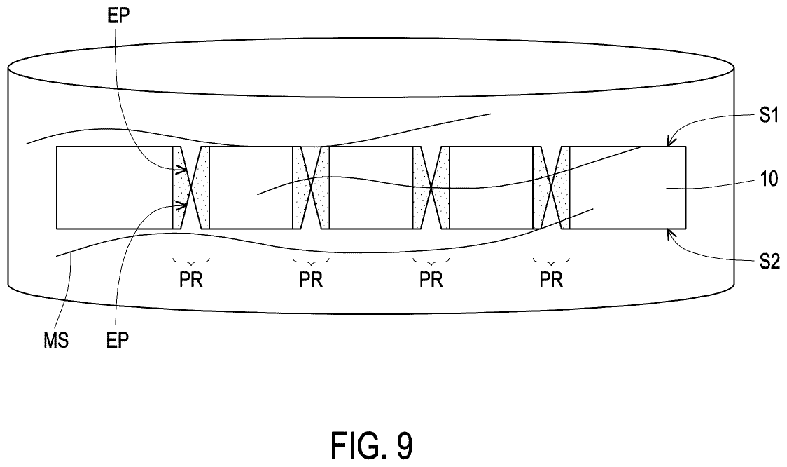

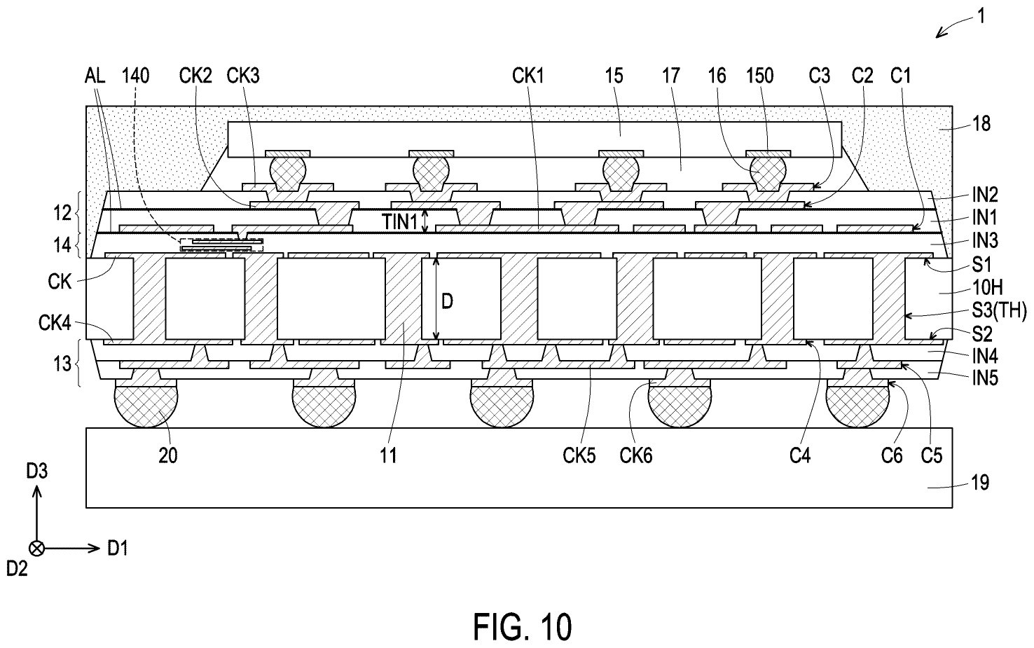

FIG. 1 is a cross-sectional schematic view of a partial region on two opposite surfaces of a substrate irradiated with a laser. FIG. 2 is a cross-sectional schematic view of performing an etching step. FIG. 3 is a cross-sectional schematic view of performing a buffer layer coating step. FIG. 4 is an enlarged schematic view of a region R1 of FIG. 3. FIG. 5 is a cross-sectional schematic view of opposite etching profiles forming a through hole and an angle of the through hole being less than or equal to 20 degrees. FIG. 6 and FIG. 7 are respectively enlarged schematic views of a region R2 and a region R3 of FIG. 5. FIG. 8 is a schematic view of immersing a substrate irradiated with a laser in a mixed solution including an inhibitor and an etchant. FIG. 9 is a schematic view of immersing a substrate formed with opposite cone holes in a mixed solution including an inhibitor and an etchant. FIG. 10 to FIG. 14 are respectively cross-sectional schematic views of five electronic devices according to some embodiments of the disclosure. It should be noted that the following embodiments may be replaced, reorganized, and mixed with features of several different embodiments to complete other embodiments without departing from the spirit of the disclosure. Features in various embodiments may be arbitrarily mixed and matched for use as long as the features do not violate the spirit of the disclosure or conflict with each other.

According to some embodiments of the disclosure, the manufacturing method of the electronic device having the through-hole substrate may include: irradiating a partial region (for example, a region PR) on two opposite surfaces (for example, a first surface S1 and a second surface S2) of a substrate 10 with a laser LS, as shown in FIG. 1; and performing a through-hole formation step in the partial region (for example, the region PR) of the substrate 10, as shown in FIG. to FIG. 2 7. The through-hole formation step may include: performing an etching step to form opposite etching profiles EP in the partial region (for example, the region PR) on the two opposite surfaces (for example, the first surface S1 and the second surface S2) of the substrate 10, as shown in FIG. 2; performing a buffer layer coating step to form a buffer layer BL on the two opposite surfaces (for example, the first surface S1 and the second surface S2) of the substrate 10 and the opposite etching profiles EP, as shown in FIG. 3 and FIG. 4; repeating the etching step (refer to FIG. 2) and the buffer layer coating step (refer to FIG. 3 and FIG. 4) until the opposite etching profiles EP form a through hole TH, as shown in FIG. 5; and confirming whether an angle θ of the through hole TH meets a specification. According to some embodiments, the angle θ of the through hole TH is less than or equal to 30 degrees or less than or equal to 20 degrees, as shown in FIG. 5.

In detail, FIG. 1 illustrates steps of laser modification. The laser LS may be used to irradiate a region to be modified or a region to be formed with a through hole (for example, the region PR) of the substrate 10 from the first surface S1 or the second surface S2 of the substrate 10 to modify the region PR. The “modification” referred to in the disclosure refers to the destruction of bonds in the partial region of the substrate 10 through laser or other suitable processing manners, so that the structural strength of the partial region is weakened. In some embodiments, the laser LS may penetrate the substrate 10. The material of the substrate 10 includes, for example, glass, ceramics, a wafer, a semiconductor material, or other inorganic materials.

FIG. 2 illustrates steps of etching. Since laser modification can improve etching efficiency, after immersing the laser-modified substrate 10 in the etchant, the etching rate of the laser-modified region PR of the substrate 10 is greater than the etching rate of a region without laser modification (for example, a region other than the region PR) of the substrate 10, so that the opposite etching profiles EP (for example, the cone holes, but not limited thereto) may be respectively formed in the partial region (for example, the region PR) on the two opposite surfaces (for example, the first surface S1 and the second surface S2) of the substrate 10 until the opposite etching profiles EP are communicated to form the through hole, but not limited thereto. According to some embodiments, the etchant may be provided from the first surface S1 or the second surface S2 until the through hole is formed. According to some embodiments, the etchant may include an acidic or alkaline etchant, wherein the acidic etchant includes hydrofluoric acid, and the alkaline etchant includes sodium hydroxide, but not limited thereto. The electronic device adopting the through-hole substrate can reduce raw material and production costs or improve yield. In addition, the through-hole substrate can have an improved electrical insulation ability, so energy loss caused by leakage current can be reduced or heating caused by leakage current under high-speed operation can be improved, so that the manufactured electronic device can better meet the standards of energy conservation and carbon reduction.

FIG. 3 and FIG. 4 illustrate repeating the buffer layer coating step until the through-hole substrate is formed. The buffer layer BL can reduce the etching rate through reducing the contact between the substrate 10 and the etchant. In some embodiments, the buffer layer BL may be formed on the two opposite surfaces (for example, the first surface S1 and the second surface S2) of the substrate 10 and the opposite etching profiles EP through immersing the substrate 10 formed with the etching profiles EP in the inhibitor or through chemical vapor deposition (CVD). The inhibitor may include an organic material or an inorganic material, such as silicon nitride (SiNₓ), silicon oxynitride (SiOₓN_{y}), aluminum oxide (Al₂O₃), hafnium dioxide (HfO₂), indium tin oxide (ITO), indium zinc oxide (IZO), sodium phosphate (Na₃PO₄), sodium fluoride (NaF), potassium phosphate (K₃PO₄), potassium fluoride (KF), ammonium fluoride (NH₄F), ammonium phosphate ((NH₄)₃PO₄), organosilane, or a combination of the above, but not limited thereto.

Using the concentration gradient characteristics of the inhibitor (the concentration of the inhibitor is from high to low from the opening of the etching profile EP to the bottom of the etching profile EP) or the generation characteristics of chemical vapor deposition, a thickness TBL of the buffer layer BL formed on the etching profile EP is from thick to thin from the opening of the etching profile EP to the bottom of the etching profile EP. The thickness TBL of the buffer layer BL is calculated in a direction perpendicular to a substrate surface (for example, the first surface S1, the second surface S2, or an inner wall S3 of the etching profile EP), as shown in FIG. 4. In some embodiments, the buffer layer BL does not cover the bottom of the etching profile EP, but not limited thereto.

After the buffer layer coating step, the etching step may be performed again (see FIG. 2). Since the thickness TBL of the buffer layer BL formed on the etching profile EP is from thick to thin from the opening of the etching profile EP to the bottom of the etching profile EP, as shown in FIG. 4, the etchant in the etching step (refer to FIG. 2) has a higher etching rate at the bottom of the etching profile EP than at the opening of the etching profile EP. In other words, through the buffer layer coating step, the modulation of the regional etching rate can be achieved, so that, for example, the rate of the modified region PR of the substrate 10 being removed by the etchant in a longitudinal direction (for example, a direction D3 or a reverse direction thereof) is higher than the rate of being removed by the etchant in a transverse direction (for example, a direction D1 or a reverse direction thereof or a direction D2 or a reverse direction thereof).

In some embodiments, the etchant in the etching step may also remove at least part of the buffer layer BL, so the buffer layer coating step may be followed after the etching step to achieve the modulation of the regional etching rate. In some embodiments, after performing the repeated buffer layer coating step or the repeated etching step, monitoring and feed backing changes in the concentration of the inhibitor are included. For example, monitoring may be performed through a real-time concentration monitoring system, and when the concentration of the inhibitor is lower than a preset value, an alarm coupled to the concentration monitoring system is activated, but not limited thereto.

The etching step (refer to FIG. 2) and the buffer layer coating step (refer to FIG. 3 and FIG. 4) may be repeated until the opposite etching profiles EP form the through hole TH, as shown in FIG. 5. The through hole TH is an opening penetrating the substrate 10, and the inner wall S3 of the through hole TH is connected to the first surface S1 and the second surface S2 of the substrate 10. In other words, a depth D of the through hole TH is equal to a thickness T10 of the substrate 10, wherein the thickness T10 of the substrate 10 is the maximum distance between the first surface S1 of the substrate 10 and the second surface S2 of the substrate 10 in the direction D3. According to some embodiments, the through hole TH has a depth greater than or equal to 0.04 mm and less than or equal to 0.9 mm.

After forming the through hole TH penetrating the substrate 10, whether the angle θ of the through hole TH meets the specification may be then confirmed, such as confirming whether the angle θ of the through hole TH is less than or equal to 20 degrees. For example, use an optical microscope (OM), a 3D-OM, or an automated optical inspection (AOI) system to confirm the angle θ of the through hole TH, but not limited thereto. The angle θ of the through hole TH refers to an included angle between an extension line EL of the inner wall S3 of the through hole TH and a normal N of the first surface S1 (or the second surface S2). In some embodiments, if it is confirmed that the angle θ of the through hole TH is less than or equal to 20 degrees, the through-hole formation step is terminated. If it is confirmed that the angle θ of the through hole TH is greater than 20 degrees, the buffer layer coating step and the etching step are repeated until the angle θ of the through hole TH is less than or equal to 20 degrees. Specifically, after etching through the substrate 10, if it is confirmed that the angle θ of the through hole TH meets the specification, it means that the production of a through-hole substrate 10H is completed, so there is no need to perform the buffer layer coating step and the etching step again. On the other hand, if it is confirmed that the angle θ of the through hole TH does not meet the specification, the buffer layer coating step and the etching step may be performed again, and the modulation of the regional etching rate can be achieved through controlling the design parameters of the buffer layer BL (for example, the region thickness, the coverage range, etc. of the buffer layer BL), so as to form the through hole TH meeting the angle specification. In some embodiments, as shown in FIG. 2 and FIG. 3, the etching step and the buffer layer coating step may be separately performed. In addition, each etching step after etching through the substrate 10 may be followed by a through hole angle confirmation step. If it is confirmed that the angle θ of the through hole TH meets the specification, there is no need to form the buffer layer BL again. Therefore, the number of the etching step may be greater than the number of the buffer layer coating step. For example, if the number of the buffer layer coating step is X, the number of the etching step may be X+1, but not limited thereto. According to some embodiments, the angle θ of the through hole TH may be checked through an optical detection system (OM), but not limited thereto.

Please refer to FIG. FIG. 5 to 7. After confirming that the angle θ of the through hole TH is less than or equal to 20 degrees, the production of the through-hole substrate 10H is completed. In some embodiments, the ratio of a width W of the through hole TH to the depth D of the through hole TH may be 0.01 to 0.5, that is, 0.01≤W/D≤0.5, but not limited thereto. The width W of the through hole TH is the minimum distance between the opposite inner wall S3 of the through hole TH in the transverse direction (for example, the direction D1 or the direction D2) in the cross-sectional view. According to some embodiments, the ratio of the maximum distance to the minimum distance may be between 1.1 and 1.5. The electronic device can have improved electrical characteristics trough the above design, but not limited thereto.

The through-hole substrate 10H has the first surface S1, the second surface S2 opposite to the first surface S1, and the through hole TH, wherein the inner wall S3 of the through hole TH is connected to the first surface S1 and the second surface S2. The first surface S1 and the second surface S2 of the through-hole substrate 10H are the first surface S1 and the second surface S2 of the substrate 10. In the etching step shown in FIG. 2, the first surface S1 and the second surface S2 are etched without being covered by a photoresist and/or the buffer layer BL, that is, the first surface S1 and the second surface S2 directly contact the etchant. In addition, even if the etching is performed after the buffer layer coating step, the time, the area, and/or the probability that the first surface S1 and the second surface S2 are exposed to the etchant are longer or greater than the time, the area, and/or the probability that the inner wall S3 of the through hole TH is exposed to the etchant. Therefore, the surface roughness of the first surface S1 is, for example, greater than the surface roughness of the inner wall S3 of the through hole TH. Similarly, the surface roughness of the second surface S2 is, for example, greater than the surface roughness of the inner wall S3 of the through hole TH. In some embodiments, the ratio of the surface roughness of the inner wall S3 of the through hole TH to the surface roughness of the first surface S1 may be greater than or equal to 0.01 and less than 1. Similarly, the ratio of the surface roughness of the inner wall S3 of the through hole TH to the surface roughness of the second surface S2 may be greater than or equal to 0.01 and less than 1. According to some embodiments, the average surface roughness of the inner wall S3 of the through hole TH may be between 0.01 μm and 1.2 μm. Through the above design, the bonding force between a subsequent film layer and the inner wall S3 can be improved.

In some embodiments, as shown in FIG. 6, the inner wall S3 of the through hole TH may have multiple protruding structures P3, and the ratio of a maximum thickness TP3 of the protruding structures P3 to the width W of the through hole TH may be 0.001 to 0.1, that is, 0.001≤TP3/W≤0.1. For example, when the width W of the through hole TH is 200 μm, the maximum thickness TP3 of the protruding structures P3 may be 0.05 μm to 10 μm. When the width W of the through hole TH is 100 μm, the maximum thickness TP3 of the protruding structures P3 may be 0.1 μm to 10 μm. When the width W of the through hole TH is 50 μm, the maximum thickness TP3 of the protruding structures P3 may be 0.1 μm to 5 μm. When the width W of the through hole TH is 5 μm, the maximum thickness TP3 of the protruding structures P3 may be 0.01 μm to 1 μm.

In some embodiments, as shown in FIG. 6 and FIG. 7, the first surface S1 and the second surface S2 may have multiple protruding structures (for example, a protruding structure P1 and a protruding structure P2), and the thicknesses (for example, a thickness TP1 and a thickness TP2) of the protruding structures may be 0.2 μm to 10 μm. In some embodiments, as shown in FIG. 7, in the cross-sectional view, the shape of at least one of the protruding structures may be a triangle, and a vertex angle α of the triangle ranges, for example, from 60 degrees to 175 degrees, that is, 60 degrees<α<175 degrees.

Although the above embodiment takes the etching step and the buffer layer coating step being separately performed as an example, in other embodiments, as shown in FIG. 8 and/or FIG. 9, the etching step and the buffer layer coating step may be simultaneously performed. Taking FIG. 8 as an example, simultaneously performing the etching step and the buffer layer coating step may include immersing the substrate 10 irradiated with the laser LS (refer to FIG. 1) into a mixed solution MS including an inhibitor and an etchant. Under such structure, the etchant in the mixed solution MS continuously etches the substrate 10, wherein the etching rate of the etchant for the laser-modified region PR is higher than the etching rate for the region without laser modification (for example, the region other than the region PR). At the same time, the inhibitor in the mixed solution MS deposits the buffer layer BL (see FIG. 3 and FIG. 4) on the first surface S1, the second surface S2, and the inner wall S3 due to chemical effects. Reference may be made to the above for the relevant content regarding the thickness TBL of the buffer layer BL, the modulation of the regional etching rate to be achieved, etc., which will not be reiterated. The buffer layer BL is partially removed by the etchant while being deposited to achieve a dynamic equilibrium. In this way, the etching step and the buffer layer coating step are repeated until the opposite etching profiles EP form the through hole TH, as shown in FIG. 5, and the through hole angle confirmation step is then followed. According to some embodiments, the inhibitor and an etching solution may be mixed according to a proportion to form the mixed solution MS, and the modified substrate 10 may be soaked in the mixed solution MS, wherein the volume ratio of the inhibitor to the etching solution may be greater than or equal to 0.001 and less than or equal to 0.5. For example, 1 ml of the inhibitor may be added to 1 liter of the etching solution.

As another option, as shown in FIG. 9, before immersing the substrate 10 irradiated with the laser LS (see FIG. 1) into the mixed solution MS, opposite cone holes (for example, the etching profiles EP) may be formed in the partial region PR on the two opposite surfaces (for example, the first surface S1 and the second side S2) of the substrate 10 to facilitate forming the through hole TH and/or using the concentration gradient characteristics of the inhibitor (the concentration of the inhibitor is from high to low from the opening of the etching profile EP to the bottom of the etching profile EP) to enable the thickness TBL of the formed buffer layer BL to be from thick to thin from the opening of the etching profile EP to the bottom of the etching profile EP.

In some embodiments, as shown in FIG. 10, after completing the production of the through-hole substrate 10H, the manufacturing method of the electronic device having the through-hole substrate may further include: providing a conductive member 11 in the through hole TH; and providing a first circuit structure 12 and a second circuit structure 13 on the first surface S1 and the second surface S2 of the through-hole substrate 10H, wherein the first circuit structure 12 is electrically connected to the second circuit structure 13 through the conductive member 11.

The conductive member 11 may be used to electrically connect multiple conductive structures respectively located on the first surface S1 and the second surface S2 of the through-hole substrate 10H. For example, the material of the conductive member 11 may include metal, alloy, or a combination thereof, and the method of forming the conductive member 11 may include electroless plating, electroplating, atomic deposition, vapor deposition, or a combination thereof, but not limited thereto. In some embodiments, as shown in FIG. 10, the number of the conductive members 11 may be multiple, and the conductive members 11 are formed in multiple through holes TH. For example, each through hole TH may be provided with a corresponding conductive member 11 and the conductive member 11 may fill the through hole TH, but not limited thereto. Taking FIG. 10 as an example, the conductive member 11 may include a conductive pillar. According to some embodiments, the conductive member 11 may include a single layer or a multi-layer stack. For example, when the conductive member 11 includes the multi-layer stack, the conductive member 11 may include multiple sub-layers, wherein a layer may be a seed layer, and the seed layer may be disposed on the first surface S1, the second surface S2, and a sidewall of the through hole TH of the through-hole substrate 10H. After forming the seed layer, a conductive layer may be formed on the seed layer. The thickness of the conductive layer is thicker than the seed layer. The bonding force between the through-hole substrate 10H and the conductive layer can be improved or the electrical characteristics of the electronic device can be improved through configuring the seed layer, but not limited thereto. The materials of the seed layer and the conductive layer may include copper (Cu), titanium (Ti), aluminum (Al), molybdenum (Mo), nickel (Ni), ruthenium (Ru), tantalum (Ta), tungsten (W), nitride, carbide, other conductive materials, or any combination of the above, but not limited thereto.

The first circuit structure 12 and the second circuit structure 13 may also be referred to as redistribution structures. The redistribution structure may be electrically connected to a chip or other electronic elements through a solder ball or other bonding elements. The redistribution structure may include at least one dielectric layer and at least one conductive layer alternately stacked along the direction D3. Through the at least one dielectric layer and the at least one conductive layer, a circuit may be redistributed and/or the fan-out or fan-in area of the circuit may be increased, or different electronic elements may be electrically connected to each other through the redistribution structure. For example, the pitch of two adjacent contact pads at one end of the redistribution structure contacting the electronic element may be less than or equal to the pitch of two adjacent contact pads at the end of the redistribution structure away from the electronic element. Therefore, the redistribution structure may adjust the fan-out condition of the circuit or electrically connect a circuit structure/electronic element having a first pitch to a circuit structure/electronic element having a second pitch, but not limited thereto. The method of forming the redistribution structure may include forming the at least one dielectric layer and the at least one conductive layer using a photolithography process, a surface treatment process, a laser process, an electroplating process, a deposition process, or other processes. The surface treatment process includes roughening or activating the surface of the dielectric layer or the surface of the conductive layer to improve the adhesion ability thereof, such as improving the bonding force with the subsequent film layer by increasing the surface roughness.

Taking FIG. 10 as an example, the first circuit structure 12 may include a conductive layer C1, a dielectric layer IN1, an adjustment layer AL, a conductive layer C2, a dielectric layer IN2, and a conductive layer C3 sequentially disposed on the first surface S1 of the through-hole substrate 10H, but not limited thereto. The materials of the dielectric layer IN1 and the dielectric layer IN2 may include polyimide (PI), photosensitive polyimide (PSPI), lead monoxide (PBO), epoxy, polymer, Ajinomoto build-up film (ABF), silicon oxide, silicon nitride, or a combination of the above, but not limited thereto. Each of the conductive layer C1, the conductive layer C2, and the conductive layer C3 may be a single conductive layer or a conductive stack. When the conductive layer C1, the conductive layer C2, and the conductive layer C3 are multi-layers or conductive stacks, the combination may be similar to the conductive member 11, which will not be reiterated. In addition, the materials of the conductive layer C1, the conductive layer C2, and the conductive layer C3 may include metal, alloy, or a combination thereof or may be the same material as the conductive member 11.

The conductive layer C1 may be a patterned conductive layer and may include multiple circuits CK1. The dielectric layer IN1 is disposed on the conductive layer C1. The conductive layer C2 is disposed on the dielectric layer IN1. The conductive layer C2 may be a patterned conductive layer and may include multiple circuits CK2. At least one circuit CK2 may penetrate the dielectric layer IN1 and be electrically connected to the corresponding circuit CK1. The dielectric layer IN2 is disposed on the dielectric layer IN1 and the conductive layer C2. The conductive layer C3 is disposed on the dielectric layer IN2. The conductive layer C3 may be a patterned conductive layer and may include multiple contact pads CK3. At least one contact pad CK3 may penetrate the dielectric layer IN2 and be electrically connected to the corresponding circuit CK2.

The second circuit structure 13 may include a conductive layer C4, a dielectric layer IN4, a conductive layer C5, a dielectric layer IN5, and a conductive layer C6 sequentially disposed on the second surface S2 of the through-hole substrate 10H, but not limited thereto. Reference may be made to the materials of the dielectric layer IN1 and the dielectric layer IN2 for the materials of the dielectric layer IN4 and the dielectric layer IN5, which will not be reiterated. Each of the conductive layer C4, the conductive layer C5, and the conductive layer C6 may be a single conductive layer or a conductive stack. In addition, reference may be made to the materials of the conductive layer C1, the conductive layer C2, and the conductive layer C3 for the materials of the conductive layer C4, the conductive layer C5, and the conductive layer C6, which will not be reiterated.

The conductive layer C4 may be a patterned conductive layer and may include multiple circuits CK4. At least one circuit CK4 may be electrically connected to the corresponding conductive member 11. The dielectric layer IN4 is disposed on the conductive layer C4. The conductive layer C5 is disposed on the dielectric layer IN4. The conductive layer C5 may be a patterned conductive layer and may include multiple circuits CK5. At least one circuit CK5 may penetrate the dielectric layer IN4 and be electrically connected to the corresponding circuit CK4. The dielectric layer IN5 is disposed on the dielectric layer IN4 and the conductive layer C5. The conductive layer C6 is disposed on the dielectric layer IN5. The conductive layer C6 may be a patterned conductive layer and may include multiple contact pads CK6. At least one contact pad CK6 may penetrate the dielectric layer IN5 and be electrically connected to the corresponding circuit CK5.

In some embodiments, as shown in FIG. 10, the adjustment layer AL may be disposed between the dielectric layer and the conductive layer. The coefficient of thermal expansion (CTE) of the adjustment layer AL may be less than or equal to the coefficient of thermal expansion of the dielectric layer. According to some embodiments, the trend of thermal expansion of the adjustment layer AL is opposite to the trend of thermal expansion of the dielectric layer. For example, when temperature changes, two sides of the dielectric layer warp upward along the direction D3, but two sides of the adjustment layer AL warp downward along the reverse direction of the direction D3, so configuring the adjustment layer AL can improve the warping of the electronic device. The material of the adjustment layer AL may include an organic material or an inorganic material.

In some embodiments, as shown in FIG. 10, the manufacturing method of the electronic device having the through-hole substrate may also optionally include: forming an element integration layer 14 on the first surface S1 of the through-hole substrate 10H; bonding an electronic element 15 to the first circuit structure 12 through a connecting member 16; forming an underfill 17 between the electronic element 15 and the first circuit structure 12; forming a packaging layer 18 on the first circuit structure 12, the underfill 17, and the electronic element 15; and bonding the second circuit structure 13 to a circuit board 19 through a connecting member 20.

In some embodiments, the element integration layer 14 may be disposed between the through-hole substrate 10H and the first circuit structure 12 and may include a dielectric layer IN3, an electronic element 140 disposed in the dielectric layer IN3, and multiple circuits CK. The electronic element 140 may be electrically connected to the first circuit structure 12, and the electronic element 15 may be electrically connected to the electronic element 140 through the connecting member 16 and the first circuit structure 12. According to different requirements, the electronic element 140 may include an active element, a passive element, or a combination of the above. For example, the electronic element 140 may include a transistor or an integrated passive device (IPD), but not limited thereto. The dielectric layer IN3 may be a single layer or a composite layer, and reference may be made to the description of the dielectric layer IN1 for the material of the dielectric layer IN3, which will not be reiterated. At least one circuit CK may be electrically connected to the corresponding conductive member 11. Although not shown, at least one circuit CK may be electrically connected to the corresponding circuit CK1, and the electronic element 140 may be electrically connected to the circuit board 19 through the connecting member 16, the first circuit structure 12, the element integration layer 14, the conductive member 11, the second circuit structure 13, and the connecting member 20.

The electronic element 15 may be a digital chip, an analog chip, a mixed-signal chip, a logic chip, a sensor chip, a semiconductor-related process structure, a resistor, a capacitor, an inductor, a semiconductor-related process structure disposed on a substrate (for example, polyimide, glass, a silicon base, or other suitable substrate materials), other types of integrated circuit chips, or a combination of the above. In some embodiments, the electronic element 15 may include multiple chips stacked on top of each other. In some embodiments, the electronic element 15 may be transferred onto the first circuit structure 12 through a pick and place (PnP) process, and multiple pads 150 of the electronic element 15 may be bonded to multiple connecting members 16. A surface where the pads 150 in the electronic element 15 are located is an active surface, and a surface opposite to the active surface is a back surface of the electronic element 15. In other embodiments, although not shown in FIG. 10, multiple electronic elements may be transferred onto the first circuit structure 12 and bonded to the first circuit structure 12. The electronic elements may include the electronic elements with different design parameters such as usage, size, type, shape, pad number, and/or pad pitch, but not limited thereto. The connecting member 16 may be a solder ball, a micro-bump, or other conductive bonding members.

The underfill 17 surrounds the connecting members 16 to protect the connecting members 16 or improve the adhesion between the first circuit structure 12 and the electronic element 15.

The packaging layer 18 surrounds the electronic element 15. For example, in the cross-sectional view, the packaging layer 18 at least contacts one side surface of the electronic element 15. The material of the packaging layer 18 includes, for example, molding compound, resin (for example, epoxy, polymer, or a combination thereof, but not limited thereto. In some embodiments, although not shown, the packaging layer 18 may be thinned through a planarization process. The planarization process may include a mechanical grinding process, a chemical mechanical polishing (CMP) process, or a combination of the above.

The connecting member 20 may bond the contact pads CK6 of the second circuit structure 13 to the circuit board 19. The connecting member 20 may be a solder ball, a micro-bump, or other conductive bonding members.

After the second circuit structure 13 is bonded to the circuit board 19, the production of the electronic device 1 is initially completed. According to some embodiments of the disclosure, the electronic device 1 may include the through-hole substrate 10H, the conductive member 11, the electronic element 15, and the circuit board 19. The through-hole substrate 10H has the first surface S1, the second surface S2 opposite to the first surface S1, and the through hole TH, wherein the inner wall S3 of the through hole TH is connected to the first surface S1 and the second surface S2. The conductive member 11 is disposed in the through hole TH. The electronic element 15 is disposed on the first surface S1 and is electrically connected to the circuit board 20 through the conductive member 11. The surface roughness of the first surface S1 is greater than the surface roughness of the inner wall S3 of the through hole TH.

In some embodiments, as mentioned above, the surface roughness of the second surface S2 may also be greater than the surface roughness of the inner wall S3 of the through hole TH. In some embodiments, as mentioned above, the angle θ (refer to FIG. 5) of the through hole TH is, for example, less than or equal to 20 degrees. In some embodiments, as mentioned above, the ratio of the width W (refer to FIG. 5) of the through hole TH to the depth D (refer to FIG. 5) of the through hole TH is, for example, 0.01 to 0.5. In some embodiments, as mentioned above, the inner wall S3 of the through hole TH may have the protruding structures P3 (refer to FIG. 6), and the ratio of the maximum thickness TP3 of the protruding structures P3 to the width W of the through hole TH is, for example, 0.001 to 0.1. In some embodiments, as mentioned above, the first surface S1 and the second surface S2 may have multiple protruding structures (refer to the protruding structure P1 and the protruding structure P2 of FIG. 6), and the thicknesses (refer to the thickness TP1 and the thickness TP2 of FIG. 6) of the protruding structures are, for example, 0.2 μm to 10 μm. In some embodiments, as mentioned above, in the cross-sectional view, the shape of at least one of the protruding structures may be a triangle, and the vertex angle α (refer to FIG. 7) of the triangle ranges, for example, from 60 degrees to 175 degrees, for adhesion purpose, but not limited thereto. In some embodiments, as mentioned above, the electronic device 1 may also optionally include the first circuit structure 12, the second circuit structure 13, the element integration layer 14, the connecting member 16, the underfill 17, the packaging layer 18, and/or the connecting member 20, but not limited thereto. According to different requirements, the electronic device 1 may further include one or more elements or film layers, or the electronic device 1 may omit one or more of the above elements or film layers.

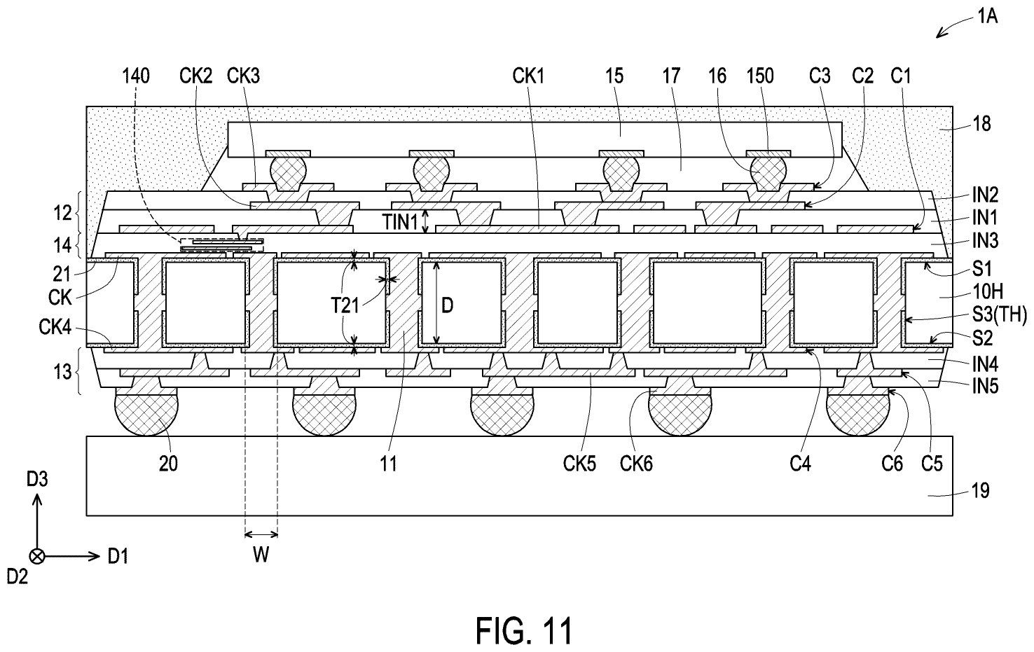

Please refer to FIG. 11. The main difference between an electronic device 1A and the electronic device 1 of FIG. 10 is that the electronic device 1A also includes a protective layer 21 covering the through-hole substrate 10H. Correspondingly, the manufacturing method of the electronic device having the through-hole substrate may also include: covering the side wall of the through-hole substrate 10H with the protective layer 21. The protective layer 21 may be used to improve the adhesion between the through-hole substrate 10H and the conductive member 11, thereby improving the detachment issue between the through-hole substrate 10H and the conductive member 11. In addition, the protective layer 21 may use strain to release internal stress generated by heat or other processes, thereby improving the structural strength of the through-hole substrate 10H or reducing the generation of cracks in the through-hole substrate 10H. For example, the material of the protective layer 21 may include polyimide (PI), parylene, benzocyclobutene (BCB), epoxy, polycarbonate (PC), polyethylene terephthalate (PET), polyethylene naphthalate (PEN), other suitable materials, or a combination of the above.

In some embodiments, the method of forming the protective layer 21 may include forming the material of the protective layer 21 on the first surface S1, the second surface S2, and the inner wall S3 through a chemical vapor deposition process. In other embodiments, the method of forming the protective layer 21 may include immersing the through-hole substrate 10H in a polymer solution. Before immersing the through-hole substrate 10H in the polymer solution, surface treatment may be optionally performed on the through-hole substrate 10H to improve the adhesion of the protective layer 21 to the through-hole substrate 10H or to reduce the risk of detachment of the protective layer 21 from the through-hole substrate 10H. The surface treatment may include a cleaning step, a plasma treatment step, a laser irradiation step, a chemical treatment step, a heating step, other suitable steps, or a combination of the above.

In some embodiments, considering process costs, time, yield, and/or the structural strength of the through-hole substrate 10H, a thickness T21 of the protective layer 21 is 0.01 μm to 10 μm, that is, 0.01 μm≤T21≤10 μm. The thickness T21 of the protective layer 21 is measured from a vertical direction (or a normal direction) of a configuration surface (for example, the first surface S1, the second surface S2, and the inner wall S3). In some embodiments, the ratio of the thickness T21 of the protective layer 21 to the width W of the through hole TH is 0.002 to 0.2, that is, 0.002≤T21/W≤0.2 to improve the structural strength of the through-hole substrate 10H and reduce damage to the through-hole substrate 10H caused by internal stress generated by a subsequent process. For example, when W=5 μm, T21=0.1 μm to 1 μm; when W=50 μm, T21=0.1 μm to 5 μm; and when W=100 μm, T21=2 μm to 10 μm. In some embodiments, a thickness of a dielectric layer of a redistribution structure (for example, a thickness TIN1 of the dielectric layer IN1) may be greater than the thickness T21 of the protective layer 21. For example, the thickness TIN1 of the dielectric layer IN1 is 5 mm to 15 mm, that is, 5 mm≤TIN1≤15 mm, but not limited thereto. In some embodiments, as shown in FIG. 11, the protective layer 21 may expose a central part of the inner wall S3. For example, the range of the inner wall S3 covered by the protective layer 21 may be more than two-thirds of the depth of the through hole TH, and the range of the inner wall S3 exposed by the protective layer 21 (that is, the range of the inner wall S3 not covered by the protective layer 21) may be less than one-third of the depth of the through hole TH.

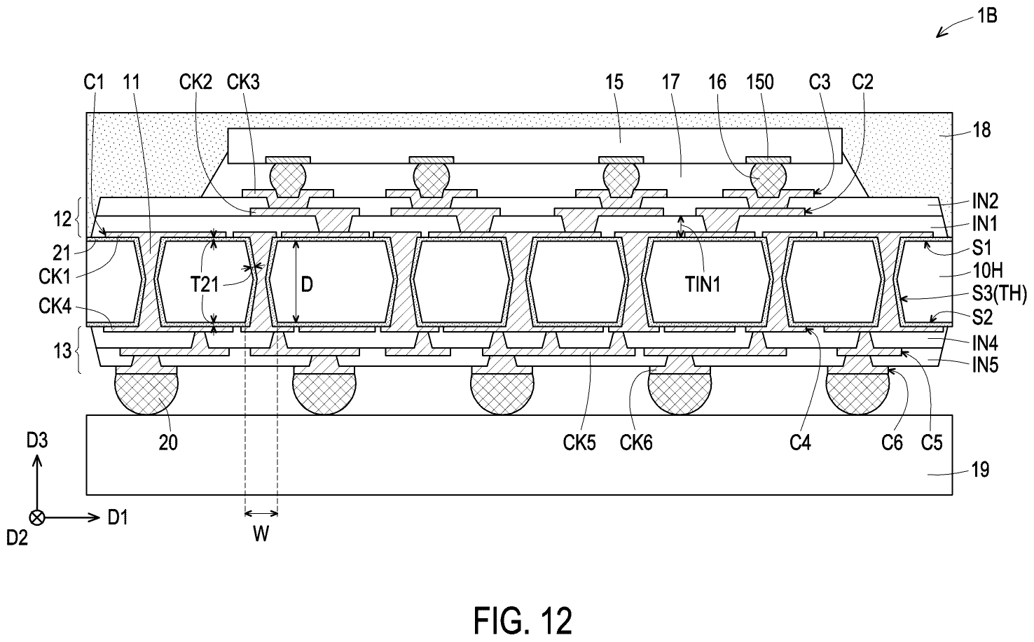

Please refer to FIG. 12. The main difference between an electronic device 1B and the electronic device 1A of FIG. 11 is explained below. In the electronic device 1B, the through hole TH and the conductive member 11 are hourglass-shaped. In addition, the inner wall S3 of the through hole TH is fully covered by the protective layer 21. In addition, the electronic device 1B does not include the element integration layer 14 of FIG. 11, and at least one circuit CK1 is electrically connected to the corresponding conductive member 11.

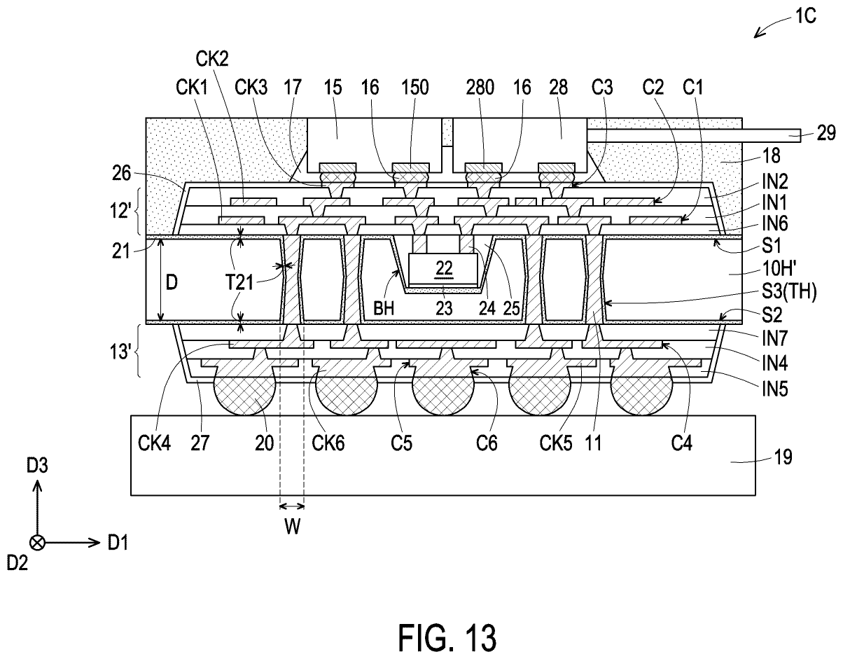

Please refer to FIG. 13. The main difference between an electronic device 1C and the electronic device 1B of FIG. 12 is explained below. In the electronic device 1C, a through-hole substrate 10H′ also includes a blind hole BH, and the electronic device 1C also includes an electronic element 22. The electronic element 22 is disposed in the blind hole BH and is electrically connected to the electronic element 15 through a first circuit structure 12′. The electronic element 22 may be a connector or other types of electronic elements, and there is no limitation here. In some embodiments, the electronic device 1C may also include an adhesion layer 23, a conductive member 24, and a filling layer 25. The electronic element 22 may be fixed in the blind hole BH through the adhesion layer 23. The adhesion layer 23 includes, for example, optical clear adhesive (OCA) or optical clear resin (OCR), but not limited thereto. The electronic element 22 may be electrically connected to the first circuit structure 12′ through the conductive member 24. The conductive member 24 includes, for example, a conductive bump or other conductive media. The filling layer 25 may fill a space in the blind hole BH that is not occupied by the electronic element 22, the adhesion layer 23, and the conductive member 24, and the filling layer 25 may expose one end of the conductive member 24 to be connected to the first circuit structure 12′. The material of the filling layer 25 may include an underfill or other insulating filling materials. In some embodiments, a top surface of the conductive member 24 and a top surface of the filling layer 25 may be flush or at the same height, but not limited thereto.

The first circuit structure 12′ may also include a dielectric layer IN6 in addition to the conductive layer C1, the dielectric layer IN1, the conductive layer C2, the dielectric layer IN2, and the conductive layer C3, and the dielectric layer IN6, the conductive layer C1, the dielectric layer IN1, the conductive layer C2, the dielectric layer IN2, and the conductive layer C3 are, for example, sequentially formed above the first surface S1. Reference may be made to the description of the dielectric layer IN1 for the material of the dielectric layer IN6, which will not be reiterated. At least one circuit CK1 in the conductive layer C1 may penetrate the dielectric layer IN6 and be electrically connected to the corresponding conductive member 11 or conductive member 24.

The electronic device 1C may also include a solder mask 26 covering the first circuit structure 12′. The solder mask 26 exposes the contact pads CK3 to provide the connecting members 16 on the contact pads CK3. In the electronic device 1C, the electronic element 15 is, for example, an electrical integrated circuit (EIC), and the electronic device 1C may also include an electronic element 28 and an optical fiber 29. Multiple pads 280 of the electronic element 28 may be connected to the contact pads CK3 through the connecting members 16. The electronic element 28 is, for example, a photonic integrated circuit (PIC), and the electronic element 28 is optically coupled to the optical fiber 29. For example, the optical fiber 29 may be embedded in the packaging layer 18 and the end of the optical fiber 29 may be connected to the electronic element 28, but not limited thereto. Other optical coupling manners between the electronic element 28 and the optical fiber 29 are also included in the protection scope of the disclosure.

A second circuit structure 13′ may also include a dielectric layer IN7 in addition to the conductive layer C4, the dielectric layer IN4, the conductive layer C5, the dielectric layer IN5, and the conductive layer C6, and the dielectric layer IN7, the conductive layer C4, the dielectric layer IN4, the conductive layer C5, the dielectric layer IN5, and the conductive layer C6 are, for example, sequentially formed above the second surface S2. Reference may be made to the description of the dielectric layer IN3 for the material of the dielectric layer IN7, which will not be reiterated. At least one circuit CK4 in the conductive layer C4 may penetrate the dielectric layer IN7 and be electrically connected to the corresponding conductive member 11.

The electronic device 1C may also include a solder mask 27 covering the second circuit structure 13′. The solder mask 27 exposes the contact pads CK6 to provide multiple connecting members 20 on the contact pads CK6.

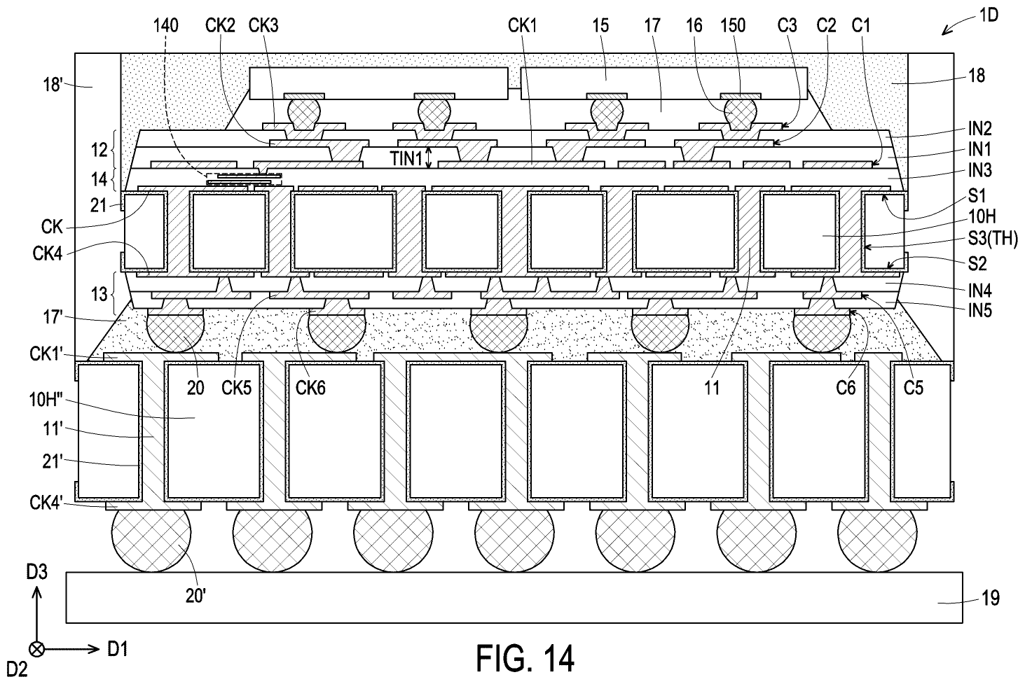

Please refer to FIG. 14. The main difference between an electronic device 1D and the electronic device 1A of FIG. 11 is explained below. In the electronic device 1D, the inner wall S3 of the through hole TH is fully covered by the protective layer 21. In addition, the electronic device 1D includes two electronic elements 15. The two electronic elements 15 may be electronic elements of the same type or different types, and there is no limitation here.

In some embodiments, as shown in FIG. 14, the electronic device 1D may also include a through-hole substrate 10H″, a protective layer 21′, multiple conductive members 11′, multiple circuits CK1′, multiple circuits CK4′, an underfill 17′, a packaging layer 18′, and multiple connecting members 20′, but not limited thereto. The relative configuration relationship of the through-hole substrate 10H″, the protective layer 21′, the conductive members 11′, the circuits CK1′, and the circuits CK4′ is similar to the relative configuration relationship of the through-hole substrate 10H, the protective layer 21, the conductive members 11, the circuits CK1, and the circuits CK4, which will not be reiterated. The connecting members 20 are respectively disposed on the circuits CK1′, the connecting members 20′ are respectively disposed on the circuits CK4′, and the through-hole substrate 10H″ is bonded and electrically connected to the circuit board 19 through the connecting members 20′. The connecting members 20′ may be electrically connected to two electronic elements 15 through the circuits CK4′, the conductive members 11′, the circuits CK1′, the connecting members 20, the second circuit structure 13, the conductive members 11, the first circuit structure 12, and the connecting members 16. The underfill 17′ surrounds the connecting members 20 to protect the connecting members 20 or improve the adhesion between the second circuit structure 13 and the through-hole substrate 10H″. The packaging layer 18′ is disposed on the through-hole substrate 10H″ and the underfill 17′ and may surround the packaging layer 18, the through-hole substrate 10H, and the second circuit structure 13. Reference may be made to the material of the packaging layer 18 for the material of the packaging layer 18′, which will not be reiterated.

In summary, in the embodiments of the disclosure, the structural strength of the substrate can be improved through designing the manufacturing method, the angle, the surface roughness, etc. of the through hole.

The above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to depart from the scope of the technical solutions of the embodiments of the disclosure.

Although the embodiments and the advantages of the disclosure have been disclosed above, it should be understood that any person skilled in the art may make changes, substitutions, and modifications without departing from the spirit and the scope of the disclosure, and the features of the embodiments may be arbitrarily mixed and replaced to form other new embodiments. In addition, the protection scope of the disclosure is not limited to processes, machines, manufactures, material compositions, devices, methods, and steps in the specific embodiments described in the specification. Any person skilled in the art may understand conventional or future-developed processes, machines, manufactures, material compositions, devices, methods, and steps from the content of the disclosure as long as the same may implement substantially the same functions or obtain substantially the same results as the embodiments described herein when used according to the disclosure. Therefore, the protection scope of the disclosure includes the above processes, machines, manufactures, material compositions, devices, methods, and steps. In addition, each claim constitutes a separate embodiment, and the protection scope of the disclosure further includes combinations of the claims and the embodiments. The protection scope of the disclosure should be defined by the appended claims.

What is claimed is:

1. An electronic device, comprising:
a through-hole substrate, having a first surface, a second surface opposite to the first surface, and a through hole, wherein an inner wall of the through hole is connected to the first surface and the second surface;
a conductive member, disposed in the through hole;
an electronic element, disposed on the first surface; and
a circuit board, wherein the electronic element is electrically connected to the circuit board through the conductive member, and a surface roughness of the first surface is greater than a surface roughness of the inner wall of the through hole.

2. The electronic device according to claim 1, wherein a surface roughness of the second surface is greater than the surface roughness of the inner wall of the through hole.

3. The electronic device according to claim 1, wherein an angle of the through hole is less than or equal to 20 degrees.

4. The electronic device according to claim 1, wherein a ratio of a width of the through hole to a depth of the through hole is 0.01 to 0.5.

5. The electronic device according to claim 1, further comprising:
a protective layer, covering the through-hole substrate.

6. The electronic device according to claim 1, wherein a ratio of the surface roughness of the inner wall of the through hole to the surface roughness of the first surface is greater than or equal to 0.01 and less than 1.

7. The electronic device according to claim 1, wherein the inner wall of the through hole has a plurality of protruding structures, and a ratio of a maximum thickness of the protruding structures to a width of the through hole is 0.001 to 0.1.

8. The electronic device according to claim 1, wherein the first surface and the second surface have a plurality of protruding structures, and a thickness of the protruding structures is 0.2 μm to 10 μm.

9. The electronic device according to claim 8, wherein in a cross-sectional view, a shape of at least one of the protruding structures is a triangle, and a vertex angle of the triangle ranges from 60 degrees to 175 degrees.

10. A manufacturing method of an electronic device having a through-hole substrate, comprising:
irradiating a partial region on two opposite surfaces of a substrate with a laser; and
performing a through-hole formation step in the partial region of the substrate, comprising:
performing an etching step to form opposite etching profiles in the partial region on the two opposite surfaces of the substrate;
performing a buffer layer coating step to form a buffer layer on the two opposite surfaces of the substrate and the opposite etching profiles; and
repeating the etching step and the buffer layer coating step until the opposite etching profiles form a through hole.

11. The manufacturing method of the electronic device having the through-hole substrate according to claim 10, further comprising:
covering the through-hole substrate with a protective layer.

12. The manufacturing method of the electronic device having the through-hole substrate according to claim 10, wherein a ratio of a width of the through hole to a depth of the through hole is 0.01 to 0.5.

13. The manufacturing method of the electronic device having the through-hole substrate according to claim 10, wherein a surface roughness of a first surface of the through-hole substrate is greater than a surface roughness of an inner wall of the through hole.

14. The manufacturing method of the electronic device having the through-hole substrate according to claim 10, further comprising:
providing a conductive member in the through hole; and
providing a first circuit structure and a second circuit structure on a first surface and a second surface of the through-hole substrate, wherein the first circuit structure is electrically connected to the second circuit structure through the conductive member.

15. The manufacturing method of the electronic device having the through-hole substrate according to claim 10, wherein a number of the etching step is greater than a number of the buffer layer coating step.

16. The manufacturing method of the electronic device having the through-hole substrate according to claim 10, wherein the through-hole formation step further comprises:
confirming whether an angle of the through hole is less than or equal to 20 degrees, wherein in response to confirming that the angle of the through hole is less than or equal to 20 degrees, the through-hole formation step is terminated, and in response to confirming that the angle of the through hole is greater than 20 degrees, the buffer layer coating step and the etching step are repeated until the angle of the through hole is less than or equal to 20 degrees.

17. The manufacturing method of the electronic device having the through-hole substrate according to claim 10, wherein the etching step and the buffer layer coating step are separately performed.

18. The manufacturing method of the electronic device having the through-hole substrate according to claim 10, wherein the etching step and the buffer layer coating step are simultaneously performed.

19. The manufacturing method of the electronic device having the through-hole substrate according to claim 18, wherein simultaneously performing the etching step and the buffer layer coating step comprises immersing the substrate irradiated with the laser in a mixed solution comprising an inhibitor and an etchant.

20. The manufacturing method of the electronic device having the through-hole substrate according to claim 19, wherein the through-hole formation step further comprises:
forming opposite cone holes in the partial region on the two opposite surfaces of the substrate before immersing the substrate irradiated with the laser in the mixed solution.
